(19) United States
(12) Patent Application Publication
(10) Pub. No.: US 2026/0349477 A1
(43) Pub. Date: Nov. 5, 2026

(54) DISPLAY SCREEN AND ELECTRONIC DEVICE

(71) Applicant: Lenovo (Beijing) Limited, Beijing (CN)

(72) Inventors: Shaopeng PENG, Beijing (CN); Gui LIU, Beijing (CN)

(21) Appl. No.: 19/658,286

(22) Filed: Apr. 24, 2026

(30) Foreign Application Priority Data
Apr. 30, 2025 (CN) 202510571477.3

(51) Int. Cl. G06F 1/16

(52) U.S. Cl. CPC G06F 1/1656; G06F 1/1616

(57) ABSTRACT

The present disclosure relates to the technical field of foldable display screens, and provides a display screen and an electronic device. The display screen includes a display panel and a protective glass layer covering the display panel; the protective glass layer includes a first piece of glass for limiting deformation of a first region of the display panel, a second piece of glass for limiting deformation of a second region of the display panel, a light-transmitting connection member for maintaining deformation of a third region of the display panel, and a third piece of glass fixed to the light-transmitting connection member; and the third piece of glass deforms synchronously with the light-transmitting connection member.

### CROSS-REFERENCES TO RELATED APPLICATION

The present disclosure claims priority to Chinese Patent Application No. 2025105714773, filed on Apr. 30, 2025, the entire content of which is incorporated herein by reference.

### FIELD OF TECHNOLOGY

The present disclosure relates to the technical field of foldable display screens, and in particular to a display screen and an electronic device.

### BACKGROUND

Many foldable display screens on the market include a screen display layer having a display function and a protective cover plate layer covering above the screen display layer. The protective cover plate layer further includes an outermost replaceable protective film, an innermost ultra-thin glass layer, and an OCA (Optically Clear Adhesive) optical adhesive layer bonding the two, and the ultra-thin glass layer can adapt to folding and bending of the foldable display screen through its own bending deformation.

However, when the protective cover plate layer of the above structure is used in actual pressing touch operation, a direct touch feeling of a user is similar to a “soft touch” feedback of PET, rather than a glass touch feedback of the ultra-thin glass layer, and a maximum thickness of the ultra-thin glass layer is only 30 um~50 um, and an increase in the thickness of the ultra-thin glass layer will lead to a decrease in its bending deformation resistance, therefore, in the related art, pressing tactile feedback of the foldable display screen is relatively soft and the touch feeling is not prominent.

In view of this, there is an urgent need in the market for a display screen having a novel structure, so as to solve the problem that, in the related art, the tactile feedback of the foldable display screen is relatively soft and a “rigid” pressing tactile feedback cannot be achieved.

### SUMMARY

The present disclosure provides a display screen and an electronic device to solve a problem that on many display screens tactile feedback of a foldable display screen is relatively soft and a “rigid” pressing tactile feedback cannot be achieved.

A display screen provided in some embodiments of the present disclosure includes a display panel and a protective glass layer covering the display panel; the protective glass layer includes a first piece of glass, a second piece of glass, a light-transmitting connection member, and a third piece of glass; the first piece of glass limits deformation of a first region corresponding to the display panel and the first piece of glass; the second piece of glass limits deformation of a second region corresponding to the display panel and the second piece of glass; the light-transmitting connection member connects the first piece of glass and the second piece of glass; the third piece of glass is fixed to the light-transmitting connection member, and the third piece of glass maintains deformation of a third region corresponding to the display panel and the light-transmitting connection member; and the third piece of glass deforms synchronously with the light-transmitting connection member.

In addition, some embodiments of the present disclosure further provide an electronic device, including a first housing, a second housing, a display screen, and a protective glass layer; the second housing is capable of rotating relative to the first housing; the display screen includes a first display region forming a first surface of the first housing, a second display region forming a second surface of the second housing, and a deformable third display region between the first display region and the second display region; the protective glass layer at least covers a surface where a display output region of the display screen is located, including at least a first piece of glass covering the first display region, a second piece of glass covering the second display region, a light-transmitting connection member covering the third display region, and a third piece of glass fixed to the light-transmitting connection member; the light-transmitting connection member is used to connect the first piece of glass and the second piece of glass; the third piece of glass maintains deformation of the third region corresponding to the display screen and the light-transmitting connection member, and the third piece of glass deforms synchronously with the light-transmitting connection member.

It should be understood that content described in this section is not intended to identify key or essential features of the embodiments of the present disclosure, nor is it intended to limit the scope of the present disclosure. Other features of the present disclosure will become readily understood from the following description.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In the drawings, identical or corresponding reference numerals indicate identical or corresponding parts.

FIG. 1 shows a first structural schematic diagram of a display screen provided in some embodiments of the present disclosure;

FIG. 2 shows a second structural schematic diagram of a display screen provided in some embodiments of the present disclosure;

FIG. 3 shows a schematic diagram of the display screen in FIG. 2 in a bent state;

FIG. 4 shows a third structural schematic diagram of a display screen provided in some embodiments of the present disclosure;

FIG. 5 shows a fourth structural schematic diagram of a display screen provided in some embodiments of the present disclosure;

FIG. 6 shows a fifth structural schematic diagram of a display screen provided in some embodiments of the present disclosure;

FIG. 7 shows a sixth structural schematic diagram of a display screen provided in some embodiments of the present disclosure;

FIG. 8 shows a first simulated stress analysis diagram of a display screen provided in some embodiments of the present disclosure;

FIG. 9 shows a second simulated stress analysis diagram of a display screen provided in some embodiments of the present disclosure;

FIG. 10 shows a schematic diagram of an electronic device provided in some embodiments of the present disclosure;

FIG. 11 shows a schematic diagram of the electronic device in FIG. 10 in a bent state;

FIG. 12 shows a second structural schematic diagram of an electronic device provided in some embodiments of the present disclosure.

Reference numerals:
1, display panel; 11, first region; 12, second region; 13, third region;
2, protective glass layer; 21, first piece of glass; 211, first inclined surface; 22, second piece of glass; 221, second inclined surface; 23, light-transmitting connection member; 231, first connection portion; 232, second connection portion; 233, central portion; 24, third piece of glass; 241, recessed groove structure;
3, first piece of glass layer;
4, first housing; 5, second housing; 6, display screen; 61, screen glass layer.

### DETAILED DESCRIPTION

Embodiments of the present disclosure are described below in conjunction with the accompanying drawings in embodiments of the present disclosure. Some terms used in embodiments of the present disclosure are only used to explain specific embodiments of the present disclosure, and are not intended to limit the present disclosure. Those of ordinary skill in the art can know that, with the development of technology and the emergence of new scenarios, the technical solutions of embodiments of the present disclosure are also applicable to similar technical problems.

The terms “first” and “second” in the specification and claims of the present disclosure and in the above accompanying drawings are used to distinguish similar objects, and are not necessarily used to describe a specific order or sequence. The terms used in this way can be interchangeable under appropriate circumstances, which is only a manner of distinction adopted when describing objects with the same attributes in embodiments of the present disclosure. In addition, the terms “comprise,” “include,” and any variations thereof are intended to cover non-exclusive inclusion, so that a process, method, system, product, or device including a series of units is not limited to those units, but can include other units not expressly listed or inherent to such process, method, product, or device.

The embodiments of the present disclosure will be described in detail below with reference to the accompanying drawings.

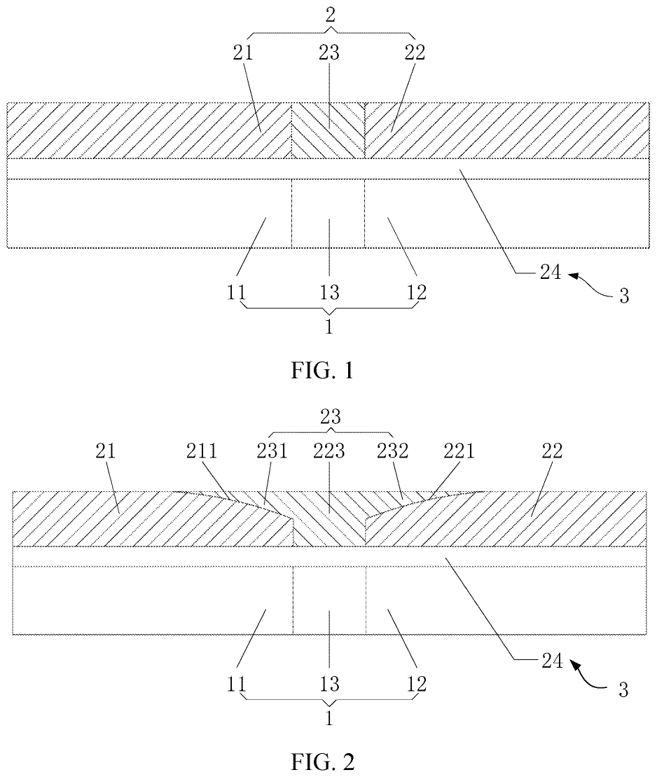

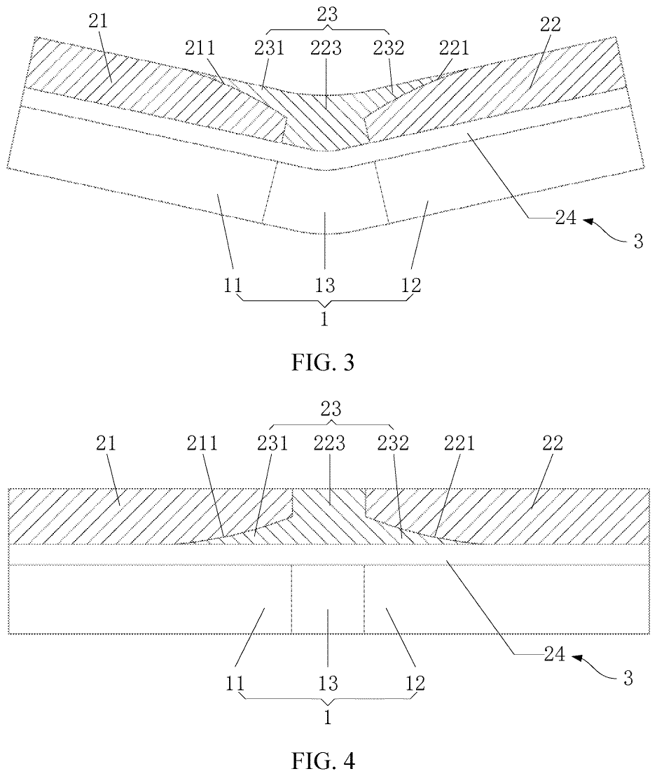

As shown in FIG. 1, some embodiments of the present disclosure provide a display screen, which may be used as, but is not limited to, a foldable display, a curved display, or other deformable displays capable of elastic deformation. The display screen includes a display panel 1 and a protective glass layer 2 covering the display panel 1; the display panel 1 and the protective glass layer 2 may be arranged to be sequentially stacked from bottom to top, and are stacked and bonded vertically through bonding using an OCA (Optically Clear Adhesive) optical adhesive, and the display panel 1 includes a first region 11, a second region 12, and a third region 13, the first region 11 and the second region 12 may be, but are not limited to, configured as constant regions having fixed sizes and fixed shapes, and the third region 13 may be configured as a deformable region having a size and/or a shape that can change.

The protective glass layer 2 includes a first piece of glass 21, a second piece of glass 22, a light-transmitting connection member 23, and a third piece of glass 24; the first piece of glass 21 limits deformation of the first region 11 corresponding to the display panel 1 and the first piece of glass 21; the first region 11 is a region jointly corresponding to the display panel 1 and the first piece of glass 21 along a thickness direction; the second piece of glass 22 limits deformation of the second region 12 corresponding to the display panel 1 and the second piece of glass 22; the second region 12 is a region jointly corresponding to the display panel 1 and the second piece of glass 22 along the thickness direction; the light-transmitting connection member 23 connects the first piece of glass 21 and the second piece of glass 22; the light-transmitting connection member 23 may be, but is not limited to, configured as a light-transmitting member, and two sides thereof may be respectively fixedly connected to the first piece of glass 21 and the second piece of glass 22 through bonding. The third piece of glass 24 is fixed to the light-transmitting connection member 23, and the third piece of glass 24 may be correspondingly fixedly disposed within the light-transmitting connection member 23, or fixedly disposed on a lower side of the light-transmitting connection member 23 along the thickness direction. The third piece of glass 24 maintains deformation of the third region 13 corresponding to the display panel 1 and the light-transmitting connection member 23; the third region 13 is a region jointly corresponding to the display panel 1 and the light-transmitting connection member 23 along the thickness direction. Moreover, when the third region 13 deforms, the third piece of glass 24 and the light-transmitting connection member 23 can synchronously deform with the third region 13 in a same form.

Since the first piece of glass 21 and the second piece of glass 22 are used to respectively limit deformation of the first region 11 and the second region 12, the first piece of glass 21 and the second piece of glass 22 may both be configured as hard rigid glass bodies having fixed shapes and not deforming, and thicknesses thereof can be flexibly set within a larger range, and may be, but are not limited to, set to be greater than 300 um. Moreover, the first piece of glass 21 and the second piece of glass 22 may be correspondingly disposed to cover one side of the display panel 1 through rigid fixed connection, such that rigidity and flatness of the first region 11 and the second region 12 of the display panel 1 can be ensured, so that when the first region 11 and the second region 12 of the display panel 1 are pressed, sufficient rigid pressing tactile feedback is provided.

Further description is provided with reference to FIG. 6. Since the light-transmitting connection member 23 is used to maintain a deformation state of the third region 13, the light-transmitting connection member 23 may be directly configured as a light-transmitting flexible connecting body, and may be, but is not limited to, formed of an elastic transparent material, and may respectively connect the first piece of glass 21 and the second piece of glass 22 with equal thickness, such that when the third region 13 corresponding to the display panel 1 is bent and curled, the light-transmitting connection member 23 can correspondingly undergo bending and curling of a same degree, thereby not affecting deformation of the third region 13 corresponding to the display panel 1 and the light-transmitting connection member 23.

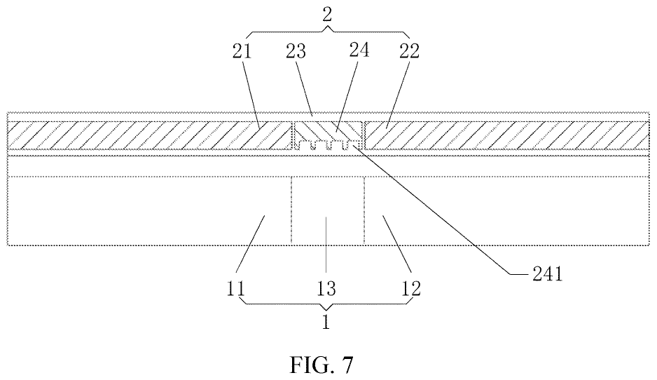

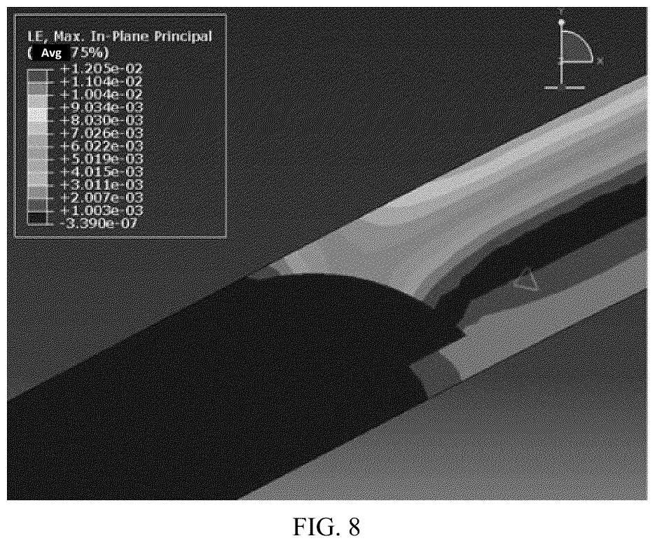

Alternatively, further description is provided with reference to FIG. 7. The light-transmitting connection member 23 includes a flexible connecting body and the third piece of glass 24 arranged in the flexible connecting body, the flexible connecting body is used to flexibly connect the first piece of glass 21 and the second piece of glass 22, and the third piece of glass 24 may be, but is not limited to, configured to be completely wrapped by the light-transmitting connection member 23, and is used to maintain a deformation state of the third region 13 corresponding to the display panel 1 and the light-transmitting connection member 23. Since the third piece of glass 24 is required to have a certain bending deformation capability at this time, the third piece of glass 24 may be configured as ultra-thin flexible glass (Ultra-Thin Glass, UTG) having a certain thickness, and the thickness may be selected to be between 10 um~50 um, so as to ensure that deformation of the display panel 1 does not cause the third piece of glass 24 to crack or be damaged.

In summary, when the display screen provided in the embodiments of the present disclosure is used as a foldable display, the protective glass layer 2 can cover a surface where an entire display output region of the display panel 1 is located, the first piece of glass 21 and the second piece of glass 22 in the protective glass layer 2 can correspondingly cover portions corresponding to non-folding regions of the display panel 1; and the light-transmitting connection member 23 and the third piece of glass 24 in the protective glass layer 2 can correspondingly cover a portion corresponding to a folding seam of the display panel 1. In this way, when the foldable display is bent at different angles, the light-transmitting connection member 23 and the third piece of glass 24 can synchronously bend with the folding seam, without affecting normal folding functions of the foldable display; the first piece of glass 21 and the second piece of glass 22 can respectively ensure rigidity and flatness of the non-folding regions of the foldable display, so that when the foldable display is operated and touched by a user, rigid glass pressing tactile feedback can be directly provided, thereby effectively solving a problem that, in the related art, tactile feedback of the foldable display screen is relatively soft and a rigid pressing tactile feedback cannot be achieved.

In addition, it should be noted that when the display screen provided in the embodiments of the present disclosure is applied to a tri-fold display screen, a quad-fold display screen, or other display screens having more folding regions, a third piece of glass, a fourth glass, and the like may be correspondingly arranged in the protective glass layer 2, and every two adjacent glass pieces are connected by one light-transmitting connection member 23.

In some embodiments, an area of the third piece of glass 24 matches an area of the display panel 1 to form a first piece of glass layer 3, and the first piece of glass layer 3 is used to cover the display panel 1,
the first piece of glass 21, the second piece of glass 22, and the light-transmitting connection member 23 form a second piece of glass layer, and the second piece of glass layer covers the first piece of glass layer 3;
a target portion of the first piece of glass layer 3 is fixed to the light-transmitting connection member 23.

For example, further detailed description is provided with reference to FIG. 1 or FIG. 2. At this time, the area of the third piece of glass 24 may be set to be equal to the area of the display panel 1, and the third piece of glass 24 may be configured as an integral piece of ultra-thin flexible glass (Ultra-Thin Glass, UTG), and the thickness may be selected to be between 10 um~50 um, so as to ensure that the third piece of glass 24 has sufficient bending deformation toughness and can satisfy use requirements of bending and curling.

The third piece of glass 24 itself forms the first piece of glass layer 3, and the first piece of glass layer 3 is fixed to the light-transmitting connection member 23 through a target portion thereof, and the target portion may be a region of the first piece of glass layer 3 corresponding to the light-transmitting connection member 23 along a thickness direction, and the target portion may be fixed by directly bonding to one side of the light-transmitting connection member 23 along the thickness direction. In this way, when the third region 13 of the display panel 1 is bent, curled, or otherwise deformed, the light-transmitting connection member 23 and the target portion of the first piece of glass layer 3 can correspondingly undergo deformation of a same degree, thereby not affecting deformation of the third region 13 corresponding to the display panel 1 and the light-transmitting connection member 23.

The first piece of glass 21, the second piece of glass 22, and the light-transmitting connection member 23 may be arranged to have equal thickness, and the first piece of glass 21 and the second piece of glass 22 may be respectively directly bonded and fixed to left and right sides of the light-transmitting connection member 23, such that the three together form a second piece of glass layer having equal thickness. In this way, when the first region 11 and the second region 12 of the display panel 1 are pressed and touched, the first piece of glass 21 and the second piece of glass 22 can directly provide sufficient rigid pressing tactile feedback to a user.

Moreover, the second piece of glass layer covers a side of the first piece of glass layer 3 facing away from the display panel 1, and the second piece of glass layer may be covered on the side of the first piece of glass layer 3 facing away from the display panel 1 by adhesive layer bonding, resin layer filling, or even electrostatic adsorption fixation.

In the above specific arrangement manner of the third piece of glass 24, the third piece of glass 24 is configured as an integral ultra-thin flexible glass layer, and a target portion of the first piece of glass layer 3 is supportingly connected to the light-transmitting connection member 23, and remaining portions are correspondingly supportingly connected to the first piece of glass 21 and the second piece of glass 22, such that an overall thicker protective glass layer 2 can be formed, and better rigid pressing tactile feedback can be provided; and when the third region 13 of the display panel 1 is bent and curled, the light-transmitting connection member 23 and the target portion of the third piece of glass 24 can correspondingly deform accordingly, so as to ensure that normal folding functions of the display panel 1 are not affected.

In some embodiments, the first piece of glass 21, the second piece of glass 22, and the third piece of glass 24 form the protective glass layer, and the third piece of glass 24 is fixed within the light-transmitting connection member 23.

For example, further detailed description is provided with reference to FIG. 6 or FIG. 7. At this time, the first piece of glass 21, the second piece of glass 22, and the third piece of glass 24 may be correspondingly arranged along a same horizontal plane, and in order to ensure flexible deformation capability of the third piece of glass 24, the thickness of the third piece of glass 24 may be set to be slightly less than the thicknesses of the first piece of glass 21 and the second piece of glass 22, and central layers of the three in a thickness direction are correspondingly aligned along a same horizontal plane.

Moreover, in addition to fixing the third piece of glass 24 within the light-transmitting connection member 23, the first piece of glass 21 and the second piece of glass 22 may also be fixed within the light-transmitting connection member 23, and a material on a side of the light-transmitting connection member 23 facing the display panel 1 may be set to be relatively softer, and a material on a side of the light-transmitting connection member 23 facing away from the display panel 1 may be set to be relatively harder, such that when regions corresponding to the first piece of glass 21 and the second piece of glass 22 in the protective glass layer are pressed, sufficient rigid pressing tactile feedback can be provided; and when a region corresponding to the third piece of glass 24 in the protective glass layer is folded and bent with the display panel 1, the third piece of glass 24 having a relatively smaller thickness can produce sufficient flexible deformation amplitude to undergo folding and bending accordingly.

In some embodiments, a recessed groove structure 241 recessed inward is further provided on a side of the third piece of glass 24 facing the display panel 1; and under a condition that the third piece of glass 24 deforms with the third region 13, a groove opening of the recessed groove structure 241 can correspondingly expand or contract.

For example, further detailed description is provided with reference to FIG. 7. A recessed groove structure 241 recessed inward is further provided on a side of the third piece of glass 24 facing the display panel 1, and the recessed groove structure 241 may be, but is not limited to, configured as a plurality of rectangular grooves arranged in parallel at intervals, such that when the third piece of glass 24 undergoes inward folding or outward folding bending deformation with the third region 13, groove openings of the recessed groove structure 241 can correspondingly expand or contract respectively, thereby further improving bending deformation capability of the third piece of glass 24, and by additionally providing the recessed groove structure 241, an overall thickness of the third piece of glass 24 can also be increased to a certain extent, thereby further improving structural strength and pressing resistance hardness of the third piece of glass 24.

Certainly, since the flexible connecting body in the light-transmitting connection member 23 is arranged to wrap an outer peripheral wall of the third piece of glass 24, an overall thickness of the flexible connecting body wrapping the third piece of glass 24 may be set to be the same as thicknesses of the first piece of glass 21 and the second piece of glass 22, such that the three can be flushly butted and cooperatively form an overall flat “rigid” touch surface.

Moreover, a wrapping material of a portion of the flexible connecting body located on an outer side of the third piece of glass 24 may be set to be relatively harder, so as to improve scratch resistance strength and further improve rigid feedback of touch control; and a wrapping material of a portion of the flexible connecting body located on an inner side of the third piece of glass 24 may be set to be relatively softer, so as to ensure better bending performance can be provided.

In some embodiments, a thickness of the third piece of glass 24 is less than a thickness of the first piece of glass 21; and the thickness of the first piece of glass 21 is the same as a thickness of the second piece of glass 22.

For example, further detailed description is provided with reference to FIG. 1 and FIG. 2. Since the third piece of glass 24 covers a surface of the third region 13 in a display output region of the display panel 1, and the third piece of glass 24 needs to deform with deformation of the third region 13, the third piece of glass 24 may be configured as ultra-thin flexible glass (Ultra-Thin Glass, UTG) having a certain thickness, so as to ensure that the third piece of glass 24 has good elastic deformation performance and avoid cracking or damage of the third piece of glass 24 when the third region 13 of the display panel 1 is folded and bent, and therefore the thickness of the third piece of glass 24 may be selected to be between 10 um~50 um.

However, the first piece of glass 21 and the second piece of glass 22 are used to limit deformation of the first region 11 and the second region 12 of the display panel 1, and are used to cover portions corresponding to non-folding regions of the display panel 1 in the protective glass layer 2. Therefore, the first piece of glass 21 and the second piece of glass 22 only need to have sufficient rigidity, and the first piece of glass 21 and the second piece of glass 22 may both be configured as tempered glass having relatively good rigidity, and thicknesses of the first piece of glass 21 and the second piece of glass 22 may be flexibly adjusted according to a size and thickness dimension of the display screen.

Therefore, by setting thicknesses of the first piece of glass 21 and the second piece of glass 22 to be greater than a thickness of the third piece of glass 24, rigidity of the first piece of glass 21 and the second piece of glass 22 can be sufficiently ensured, thereby ensuring deformation limiting effects on the first region 11 and the second region 12 of the display panel 1; and the third piece of glass 24 having a smaller thickness can have good elastic deformation performance, so as to avoid accidental cracking or damage during folding and bending deformation.

It can be understood that the present disclosure does not limit thickness setting ranges of the first piece of glass 21, the second piece of glass 22, and the third piece of glass 24, that is, those skilled in the art may adjust sizes thereof according to actual conditions, and the above descriptions are merely exemplary descriptions of ways in which target components of the present disclosure can be implemented, and are not limited to situations described in the above embodiments.

In some embodiments, the first piece of glass 21 has a first inclined surface 211, and is correspondingly connected to one side of the light-transmitting connection member 23 through the first inclined surface 211; and the second piece of glass 22 has a second inclined surface 221, and is correspondingly connected to another opposite side of the light-transmitting connection member 23 through the second inclined surface 221.

For example, further detailed description is provided with reference to FIG. 2. The first piece of glass 21 may be configured such that a side thereof facing the light-transmitting connection member 23 is the first inclined surface 211, and the second piece of glass 22 may be configured such that a side thereof facing the light-transmitting connection member 23 is the second inclined surface 221, and inclination angles of the first piece of glass 21 and the second inclined surface 221 may be, but are not limited to, set to 30°.

Since two opposite side portions of the light-transmitting connection member 23 are respectively connected to the first inclined surface 211 and the second inclined surface 221, on one hand, contact areas between the first piece of glass 21, the second piece of glass 22 and the light-transmitting connection member 23 can be increased respectively, thereby improving connection firmness.

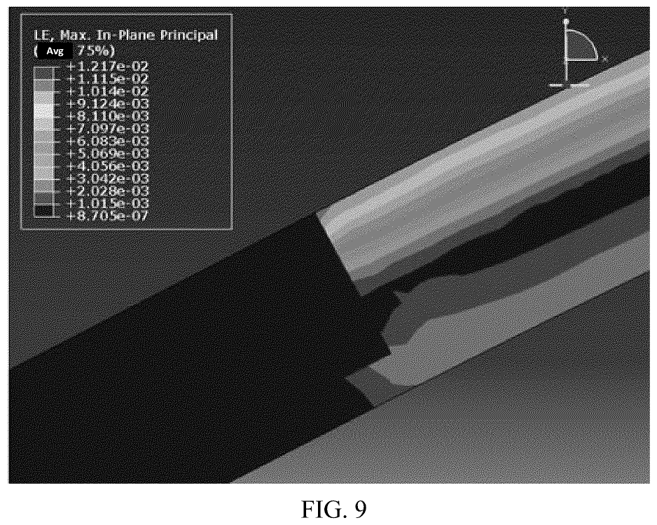

On the other hand, further description is provided with reference to FIG. 8 and FIG. 9. In FIG. 8, two opposite side portions of the light-transmitting connection member 23 are respectively connected to the first inclined surface 211 of the first piece of glass 21 and the second inclined surface 221 of the second piece of glass 22, and corresponding simulated stress analysis is performed; in FIG. 9, two opposite side portions of the light-transmitting connection member 23 are respectively connected to vertical side surfaces of the first piece of glass 21 and the second piece of glass 22, and corresponding simulated stress analysis is performed; by comparing the two figures, it can be clearly observed that when the first inclined surface 211 and the second inclined surface 221 are provided, when the display panel 1 is bent and folded, compressive stress at connection portions on both sides of the light-transmitting connection member 23 can be sufficiently relieved, thereby being more favorable for bending deformation of the light-transmitting connection member 23.

In addition, since connection contact surfaces between the first piece of glass 21, the second piece of glass 22, and the light-transmitting connection member 23 are arranged to be inclined, rather than vertically downward along a thickness direction, connection traces at connection portions between the first piece of glass 21, the second piece of glass 22, and the light-transmitting connection member 23 can be respectively “weakened,” thereby avoiding formation of boundary line-shaped connection marks, and reducing, to a greatest extent, an influence of connection portions on both sides of the light-transmitting connection member 23 on a display effect of the display panel 1.

In addition, it is worth noting that the light-transmitting connection member 23 may be selected as a colorless transparent material having a refractive index the same as or close to that of the first piece of glass 21 and the second piece of glass 22, for example, the light-transmitting connection member 23 may be, but is not limited to, configured as a colorless elastic plastic member, and may be fixedly connected to the first inclined surface 211 and the second inclined surface 221 through thermal melting or adhesive bonding, such that after the first piece of glass 21, the light-transmitting connection member 23, and the second piece of glass 22 are sequentially connected, an overall visual effect close to integral connection can be presented.

It can be understood that the present disclosure does not limit inclination angle ranges of the first inclined surface 211 and the second inclined surface 221, that is, those skilled in the art may adjust sizes thereof according to actual conditions, and the above descriptions are merely exemplary descriptions of ways in which target components of the present disclosure can be implemented, and are not limited to situations described in the above embodiments.

In some embodiments, one side edge of the first inclined surface 211 abuts against an upper surface or a lower surface of the first piece of glass 21, such that areas of the upper surface and the lower surface of the first piece of glass 21 are not equal; and one side edge of the second inclined surface 221 abuts against an upper surface or a lower surface of the second piece of glass 22, such that areas of the upper surface and the lower surface of the second piece of glass 22 are not equal.

For example, further detailed description is provided with reference to FIG. 2. At this time, one side edge of the first inclined surface 211 abuts against an upper surface of the first piece of glass 21, such that an area of the upper surface of the first piece of glass 21 is smaller than an area of a lower surface of the first piece of glass 21; and one side edge of the second inclined surface 221 abuts against an upper surface of the second piece of glass 22, such that an area of the upper surface of the second piece of glass 22 is smaller than an area of a lower surface of the second piece of glass 22. That is, the first inclined surface 211 and the second inclined surface 221 are arranged in an inverted “ [symbol] ”-shaped inclined manner.

Further detailed description is provided with reference to FIG. 4. At this time, one side edge of the first inclined surface 211 abuts against a lower surface of the first piece of glass 21, such that an area of the upper surface of the first piece of glass 21 is greater than an area of the lower surface of the first piece of glass 21; and one side edge of the second inclined surface 221 abuts against a lower surface of the second piece of glass 22, such that an area of the upper surface of the second piece of glass 22 is greater than an area of the lower surface of the second piece of glass 22. That is, the first inclined surface 211 and the second inclined surface 221 are arranged in a “ [symbol] ”-shaped inclined manner.

The above two arrangement manners of the first inclined surface 211 and the second inclined surface 221 can both enable side portions of the first piece of glass 21 and the second piece of glass 22 close to the light-transmitting connection member 23 to form a gradually reduced thickness transition portion, such that when the third region 13 of the display panel 1 and the light-transmitting connection member 23 synchronously undergo bending deformation, compressive force generated by deformation of the light-transmitting connection member 23 is respectively applied to the first inclined surface 211, the second inclined surface 221, local upper surfaces or local lower surfaces of the first piece of glass 21, and local upper surfaces or local lower surfaces of the second piece of glass 22, thereby avoiding stress concentration compression and avoiding a problem that edge portions of the first piece of glass 21 and the second piece of glass 22 are damaged by compression.

In some embodiments, the first inclined surface 211 and the second inclined surface 221 are respectively arranged on two opposite sides of the light-transmitting connection member 23 in an axis-symmetrical manner or a centrosymmetrical manner.

For example, further detailed description is provided with reference to FIG. 2 or FIG. 4. At this time, the first inclined surface 211 and the second inclined surface 221 are respectively arranged on two opposite sides of the light-transmitting connection member 23 in an axis-symmetrical manner.

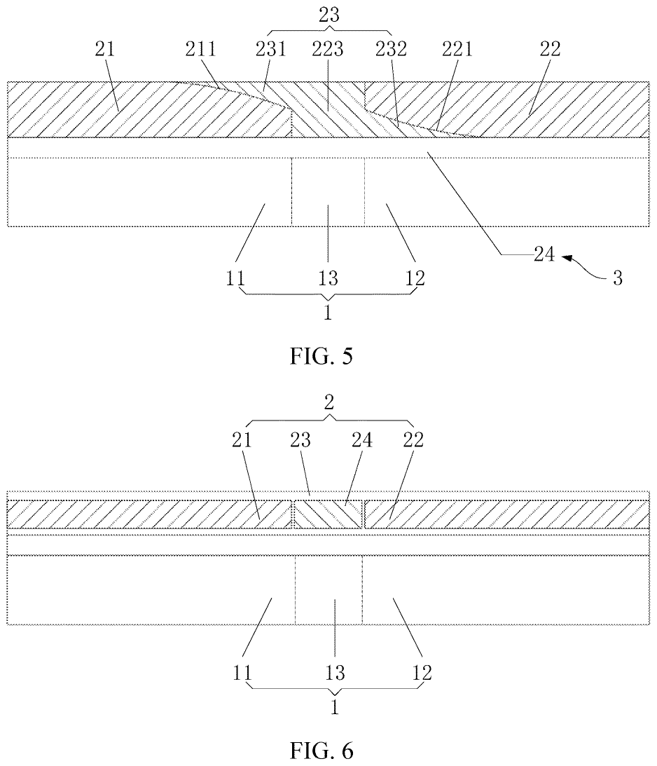

Further detailed description is provided with reference to FIG. 5. At this time, the first inclined surface 211 and the second inclined surface 221 are respectively arranged on two opposite sides of the light-transmitting connection member 23 in a centrosymmetrical manner.

The above two arrangement manners of the first inclined surface 211 and the second inclined surface 221 can both enable the first inclined surface 211 and the second inclined surface 221 to be respectively arranged on two opposite sides of the light-transmitting connection member 23 with a same inclination angle, a same area, and a same shape, such that compressive force generated by deformation of the light-transmitting connection member 23 is divided into two portions and respectively acts on the first inclined surface 211 and the second inclined surface 221 with a same magnitude, so that the first piece of glass 21 and the second piece of glass 22 can uniformly share and bear the force.

In some embodiments, a first recessed portion is formed between the first inclined surface 211 and the light-transmitting connection member 23; and a second recessed portion is formed between the second inclined surface 221 and the light-transmitting connection member 23; and the light-transmitting connection member 23 includes a first connection portion 231 flush-filled in the first recessed portion and a second connection portion 232 flush-filled in the second recessed portion.

For example, further detailed description is provided with reference to FIG. 2 or FIG. 4. Since the first recessed portion can be formed between the first inclined surface 211 and the light-transmitting connection member 23, and the second recessed portion can be formed between the second inclined surface 221 and the light-transmitting connection member 23, two opposite side portions of the light-transmitting connection member 23 can respectively extend outward to form the first connection portion 231 and the second connection portion 232, and the first connection portion 231 is flush-filled in the first recessed portion and the second connection portion 232 is flush-filled in the second recessed portion, such that the protective glass layer 2 can form a flat and regular outer contour, thereby ensuring that a lower surface of the protective glass layer 2 can seamlessly cover an upper surface of the protective glass layer 2, and enabling an upper surface of the protective glass layer 2 to form a complete flat surface for user touch.

In some embodiments, the light-transmitting connection member 23 further includes a central portion 233 arranged corresponding to the third region 13 along a thickness direction; the first connection portion 231 and the second connection portion 232 are respectively connected to two opposite sides of the central portion 233; thicknesses of the first connection portion 231 and the second connection portion 232 do not exceed a thickness of the central portion 233; and the thickness of the central portion 233, the thickness of the first piece of glass 21, and the thickness of the second piece of glass 22 are respectively the same.

For example, further detailed description is provided with reference to FIG. 2 or FIG. 4. The light-transmitting connection member 23 further includes a central portion 233 arranged corresponding to the third region 13 along the thickness direction, and the thickness of the central portion 233 may be set to be respectively equal to the thicknesses of the first piece of glass 21 and the second piece of glass 22. The first connection portion 231 and the second connection portion 232 are respectively connected to two opposite side surfaces of the central portion 233, and along a direction away from the central portion 233, thicknesses of the first connection portion 231 and the second connection portion 232 may be set to gradually decrease.

The central portion 233 can synchronously undergo bending deformation when the third region 13 of the display panel 1 undergoes bending deformation, thereby ensuring that deformation of the third region 13 corresponding to the display panel 1 and the light-transmitting connection member 23 can be effectively maintained; and since the thicknesses of the first connection portion 231 and the second connection portion 232 gradually decrease, deformation action generated by bending deformation of the central portion 233 can be gradually weakened along the first connection portion 231 and the second connection portion 232, thereby reducing compressive action on edge portions of the first piece of glass 21 and the second piece of glass 22.

In addition, some embodiments of the present disclosure further provide an electronic device, including a first housing 4, a second housing 5, a display screen 6, and a protective glass layer; the second housing 5 is capable of rotating relative to the first housing 4; the display screen includes a first display region forming a first surface of the first housing 4, a second display region forming a second surface of the second housing 5, and a deformable third display region between the first display region and the second display region; the protective glass layer at least covers a surface where a display output region of the display screen is located, including at least a first piece of glass 21 covering the first display region, a second piece of glass 22 covering the second display region, a light-transmitting connection member 23 covering the third display region, and a third piece of glass 24 fixed to the light-transmitting connection member 23; the light-transmitting connection member 23 is used to connect the first piece of glass 21 and the second piece of glass 22; and the third piece of glass 24 is used to maintain a deformation state of the third region corresponding to the display screen 6 and the light-transmitting connection member 23, and the third piece of glass 24 deforms synchronously with the light-transmitting connection member 23.

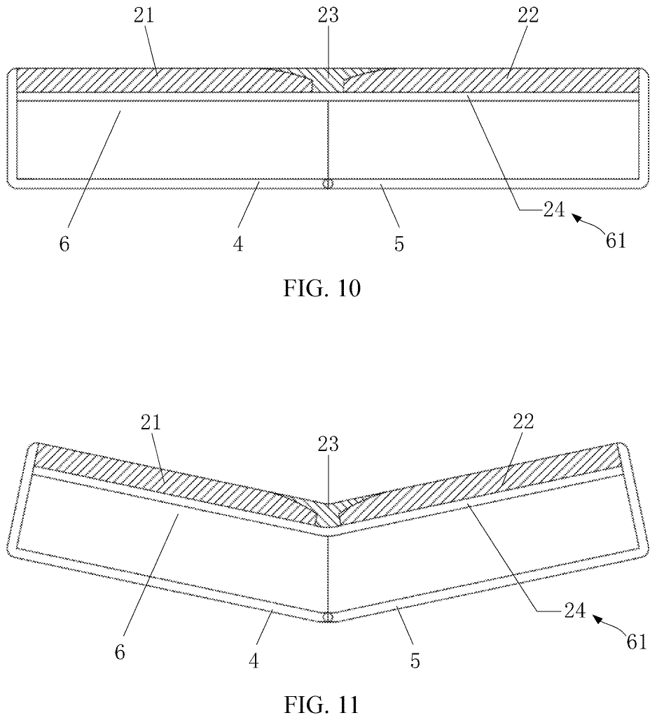

For example, further detailed description is provided with reference to FIG. 10 and FIG. 11. The electronic device provided in the embodiments of the present disclosure may be, but is not limited to, a foldable display mobile phone, a foldable display tablet, a foldable display notebook computer, or some wearable electronic devices having a screen folding function.

The electronic device includes a first housing 4, a second housing 5, a display screen 6, and a protective glass layer, the display screen includes a first display region, a second display region, and a deformable third display region located between the first display region and the second display region, and the first display region is covered by the first piece of glass 21, the second display region is covered by the second piece of glass 22, and the third display region is covered by the light-transmitting connection member 23 and at least a portion of the third piece of glass 24.

Since the third piece of glass 24 and the light-transmitting connection member 23 can deform synchronously with the third display region, the first piece of glass 21 and the second piece of glass 22 can correspondingly cover two non-folding regions of the display screen 6, and the light-transmitting connection member 23 and the third piece of glass 24 correspondingly cover a folding seam region between the two non-folding regions. In this way, when the display screen 6 is folded and bent at different angles, the light-transmitting connection member 23 and the third piece of glass 24 can synchronously bend with the folding seam region, without affecting normal folding functions of the display screen 6; and the first piece of glass 21 and the second piece of glass 22 can respectively ensure rigidity and flatness of non-folding regions of the display screen 6, such that when the display screen 6 is operated and touched by a user, rigid glass pressing tactile feedback can be directly provided, thereby solving a problem that, in the related art, tactile feedback of the foldable display screen is relatively soft and a rigid pressing tactile feedback cannot be achieved.

In some embodiments, an area of the third piece of glass 24 matches an area of the display screen 6 to form a screen glass layer 61, and the screen glass layer 61 is used to cover the display screen 6,
the first piece of glass 21, the second piece of glass 22, and the light-transmitting connection member 23 form a second piece of glass layer, and the second piece of glass layer covers the screen glass layer 61;
a target portion of the screen glass layer 61 is fixed to the light-transmitting connection member 23.

For example, further detailed description is provided with reference to FIG. 10. At this time, the third piece of glass 24 may be configured as an integral piece of ultra-thin flexible glass (Ultra-Thin Glass, UTG) having an area equal to the area of the display screen 6, and a thickness of the third piece of glass 24 may be selected to be between 10 um~50 um, so as to ensure that the third piece of glass 24 has sufficient bending deformation toughness and can satisfy use requirements of bending and curling.

The third piece of glass 24 itself forms the screen glass layer 61, and the screen glass layer 61 is fixed to the light-transmitting connection member 23 through a target portion thereof, and the target portion may be a region of the screen glass layer 61 corresponding to the light-transmitting connection member 23 along a thickness direction. Moreover, one side of the screen glass layer 61 may be directly bonded and fixed to the display screen 6 through OCA (Optically Clear Adhesive) optical adhesive, and another side of the screen glass layer 61 may be respectively bonded and fixed to the first piece of glass 21, the second piece of glass 22, and the light-transmitting connection member 23 through OCA optical adhesive.

In this way, when the third display region of the display screen 6 is bent, curled, or otherwise deformed, the light-transmitting connection member 23 and the target portion of the screen glass layer 61 can correspondingly undergo deformation of a same degree, thereby not affecting bending deformation of the third display region corresponding to the display screen 6 and the light-transmitting connection member 23.

In some embodiments, the first piece of glass 21, the second piece of glass 22, and the third piece of glass 24 form the protective glass layer, and the third piece of glass 24 is fixed within the light-transmitting connection member 23.

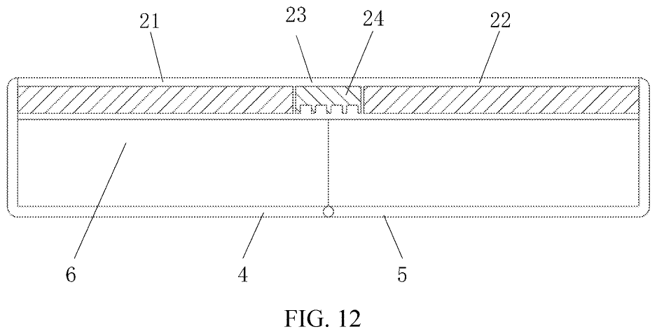

For example, further detailed description is provided with reference to FIG. 12. At this time, the first piece of glass 21, the second piece of glass 22, and the third piece of glass 24 may be correspondingly arranged along a same horizontal plane, and in order to ensure flexible deformation capability of the third piece of glass 24, the thickness of the third piece of glass 24 may be set to be slightly less than the thicknesses of the first piece of glass 21 and the second piece of glass 22, and central layers of the three in a thickness direction are correspondingly aligned along a same horizontal plane.

Moreover, in addition to fixing the third piece of glass 24 within the light-transmitting connection member 23, the first piece of glass 21 and the second piece of glass 22 may also be clamped and fixed within the light-transmitting connection member 23, and a material on a side of the light-transmitting connection member 23 facing the display screen 6 may be set to be relatively softer, and a material on a side of the light-transmitting connection member 23 facing away from the display screen 6 may be set to be relatively harder, such that when regions corresponding to the first piece of glass 21 and the second piece of glass 22 in the protective glass layer are pressed, sufficient rigid pressing tactile feedback can be provided; and when a region corresponding to the third piece of glass 24 in the protective glass layer is folded and bent with the display screen 6, the third piece of glass 24 having a relatively smaller thickness can produce sufficient flexible deformation amplitude to undergo folding and bending accordingly.

In addition, a recessed groove structure 241 may also be correspondingly provided on a side of the third piece of glass 24 facing the display screen 6; and under a condition that the third piece of glass 24 deforms with deformation of the third display region of the display screen 6, a groove opening of the recessed groove structure 241 can correspondingly expand or contract, thereby further improving bending deformation capability of the third piece of glass 24, and by additionally providing the recessed groove structure 241, an overall thickness of the third piece of glass 24 can also be increased to a certain extent, and structural strength and pressing resistance hardness of the third piece of glass 24 can be further improved.

In addition, the terms “first” and “second” are used for descriptive purposes only, and are not to be construed as indicating or implying relative importance or implicitly indicating a number of indicated technical features. Thus, features defined as “first” and “second” may explicitly or implicitly include at least one such feature. In the description of the present disclosure, “a plurality of” means two or more, unless otherwise expressly specified.

The above descriptions are merely embodiments of the present disclosure, and the scope of the present disclosure is not limited thereto. Any modifications or substitutions that can be readily conceived by those skilled in the art within the technical scope disclosed in the present disclosure shall fall within the scope of the present disclosure. Therefore, the scope of the present disclosure shall be defined by the scope of the claims.

What is claimed is:

1. A display screen, including a display panel and a protective glass layer covering the display panel;
the protective glass layer includes:
a first piece of glass, wherein the first piece of glass limits deformation of a first region corresponding to the display panel and the first piece of glass;
a second piece of glass, wherein the second piece of glass limits deformation of a second region corresponding to the display panel and the second piece of glass;
a light-transmitting connection member, wherein the light-transmitting connection member connects the first piece of glass and the second piece of glass;
a third piece of glass, fixed to the light-transmitting connection member, wherein the third piece of glass maintains deformation of a third region corresponding to the display panel and the light-transmitting connection member;
wherein the third piece of glass deforms synchronously with the light-transmitting connection member.

2. The display screen according to claim 1, wherein an area of the third piece of glass matches an area of the display panel to form a first piece of glass layer, and the first piece of glass layer is used to cover the display panel,
the first piece of glass, the second piece of glass, and the light-transmitting connection member form a second piece of glass layer, and the second piece of glass layer covers the first piece of glass layer;
a target portion of the first piece of glass layer is fixed to the light-transmitting connection member.

3. The display screen according to claim 1, wherein the first piece of glass, the second piece of glass, and the third piece of glass form the protective glass layer, and the third piece of glass is fixed within the light-transmitting connection member.

4. The display screen according to claim 3, wherein a recessed groove structure recessed inward is further provided on a side of the third piece of glass facing the display panel;
under a condition that the third piece of glass deforms synchronously with the light-transmitting connection member, a groove opening of the recessed groove structure correspondingly expands or contracts.

5. The display screen according to claim 1, wherein a thickness of the third piece of glass is less than a thickness of the first piece of glass;
the thickness of the first piece of glass is the same as a thickness of the second piece of glass.

6. The display screen according to claim 5, wherein the first piece of glass has a first inclined surface, and is correspondingly connected to one side of the light-transmitting connection member through the first inclined surface;
the second piece of glass has a second inclined surface, and is correspondingly connected to another opposite side of the light-transmitting connection member through the second inclined surface.

7. The display screen according to claim 6, wherein the first inclined surface, the second inclined surface, and the light-transmitting connection member satisfy at least one of the following:
one side edge of the first inclined surface abuts against an upper surface or a lower surface of the first piece of glass, such that areas of the upper surface and the lower surface of the first piece of glass are not equal;
one side edge of the second inclined surface abuts against an upper surface or a lower surface of the second piece of glass, such that areas of the upper surface and the lower surface of the second piece of glass are not equal;
or,
the first inclined surface and the second inclined surface are respectively arranged on two opposite sides of the light-transmitting connection member in an axis-symmetrical manner or a centrosymmetrical manner;
or,
a first recessed portion is formed between the first inclined surface and the light-transmitting connection member;
a second recessed portion is formed between the second inclined surface and the light-transmitting connection member;
the light-transmitting connection member includes a first connection portion flush-filled in the first recessed portion and a second connection portion flush-filled in the second recessed portion.

8. The display screen according to claim 7, wherein the light-transmitting connection member further includes a central portion arranged corresponding to the third region along a thickness direction;
the first connection portion and the second connection portion are respectively connected to two opposite sides of the central portion;
thicknesses of the first connection portion and the second connection portion do not exceed a thickness of the central portion;
the thickness of the central portion, the thickness of the first piece of glass, and the thickness of the second piece of glass are respectively the same.

9. An electronic device, including:
a first housing;
a second housing, wherein the second housing is capable of rotating relative to the first housing;
a display screen, including a first display region forming a first surface of the first housing, a second display region forming a second surface of the second housing, and a deformable third display region between the first display region and the second display region;
a protective glass layer, at least covering a surface where a display output region of the display screen is located, including at least a first piece of glass covering the first display region, a second piece of glass covering the second display region, a light-transmitting connection member covering the third display region, and a third piece of glass fixed to the light-transmitting connection member;
wherein the light-transmitting connection member is used to connect the first piece of glass and the second piece of glass;
the third piece of glass maintains deformation of the third region corresponding to the display screen and the light-transmitting connection member, and the third piece of glass deforms synchronously with the light-transmitting connection member.

10. The electronic device according to claim 9, wherein:
an area of the third piece of glass matches an area of the display screen to form a screen glass layer, and the screen glass layer is used to cover the display screen,
the first piece of glass, the second piece of glass, and the light-transmitting connection member form a second piece of glass layer, and the second piece of glass layer covers the screen glass layer; and
a target portion of the screen glass layer is fixed to the light-transmitting connection member.

11. The electronic device according to claim 9, wherein the first piece of glass, the second piece of glass, and the third piece of glass form the protective glass layer, and the third piece of glass is fixed within the light-transmitting connection member.

12. The electronic device according to claim 11, wherein a recessed groove structure recessed inward is further provided on a side of the third piece of glass facing the display panel;
under a condition that the third piece of glass deforms synchronously with the light-transmitting connection member, a groove opening of the recessed groove structure correspondingly expands or contracts.

13. The electronic device according to claim 9, wherein a thickness of the third piece of glass is less than a thickness of the first piece of glass;
the thickness of the first piece of glass is the same as a thickness of the second piece of glass.

14. The electronic device according to claim 13, wherein the first piece of glass has a first inclined surface, and is correspondingly connected to one side of the light-transmitting connection member through the first inclined surface;
the second piece of glass has a second inclined surface, and is correspondingly connected to another opposite side of the light-transmitting connection member through the second inclined surface.

15. The electronic device according to claim 14, wherein:
one side edge of the first inclined surface abuts against an upper surface or a lower surface of the first piece of glass, such that areas of the upper surface and the lower surface of the first piece of glass are not equal; and
one side edge of the second inclined surface abuts against an upper surface or a lower surface of the second piece of glass, such that areas of the upper surface and the lower surface of the second piece of glass are not equal.

16. The electronic device according to claim 14, wherein:
the first inclined surface and the second inclined surface are respectively arranged on two opposite sides of the light-transmitting connection member in an axis-symmetrical manner or a centrosymmetrical manner.

17. The electronic device according to claim 14, wherein:
a first recessed portion is formed between the first inclined surface and the light-transmitting connection member;
a second recessed portion is formed between the second inclined surface and the light-transmitting connection member; and
the light-transmitting connection member includes a first connection portion flush-filled in the first recessed portion and a second connection portion flush-filled in the second recessed portion.

18. The electronic device according to claim 15, wherein the light-transmitting connection member further includes a central portion arranged corresponding to the third region along a thickness direction;
the first connection portion and the second connection portion are respectively connected to two opposite sides of the central portion;
thicknesses of the first connection portion and the second connection portion do not exceed a thickness of the central portion;
the thickness of the central portion, the thickness of the first piece of glass, and the thickness of the second piece of glass are respectively the same.
